(19) United States
(12) Patent Application Publication
(10) Pub. No.: US 2025/0054821 A1
(43) Pub. Date: Feb. 13, 2025

(54) COMPOSITE CARRIER, METHOD OF MAKING AND METHOD OF USING THE COMPOSITE CARRIER IN SEMICONDUCTOR PACKAGING

(71) Applicant: Yibu Semiconductor Co., Ltd., Shanghai (CN)

(72) Inventor: Ming Li, Fremont, CA (US)

(73) Assignee: Yibu Semiconductor Co., Ltd., Shanghai (CN)

(21) Appl. No.: 18/796,024

(22) Filed: Aug. 6, 2024

(30) Foreign Application Priority Data
Aug. 9, 2023 (CN) 202311003500.6

(51) Int. Cl. H01L 23/14; H01L 23/00; H01L 23/31; H01L 23/498

(52) U.S. Cl. CPC H01L 23/145; H01L 23/3128; H01L 23/49816; H01L 23/49822; H01L 24/32; H01L 2224/32225; H01L 2924/351

(57) ABSTRACT

The present disclosure relates to a composite carrier, a method of manufacturing and a method of using the semiconductor carrier as a support carrier in the Wafer Level or Panel Level Fan-out Packaging processes. The composite carrier comprises a first support layer, a second support layer, and a stress absorption layer sandwiched between the first support layer and the second support layer. When the composite carrier is applied to semiconductor packaging processes, the first support layer and the second support layer are used for providing support for the packages being formed, and the stress absorption layer is configured to absorb the stress generated in the packaging processes, thus reducing or eliminating warpage, making it easier to perform subsequent wafer or panel processing steps, and lessening the impact of warpage on the size of the carrier and redistribution wiring accuracy.

### CROSS REFERENCE TO RELATED APPLICATION

This application claims the benefit of priority under the Paris Convention to Chinese Patent Application No. 202311003500.6A, filed Aug. 9, 2023, which is incorporated herein by reference in its entirety.

### TECHNICAL FIELD

The disclosure relates to the technical field of semiconductors, and in particular relates to a composite carrier, method of making and method of using the composite carrier in semiconductor packaging.

### BACKGROUND

With the rapid development of the semiconductor technology, the chip sizes are getting smaller and smaller, the number of signal contacts is increasing. Traditional packages can no longer meet the demand for high signal contact counts. Wafer Level Fan-out Package (or Fan-Out Wafer Level Package, FOWLP) or Panel Level Fan-out Package (Fan-Out Panel Level Package, FOPLP) technology is an embedded chip packaging method for Wafer Level or Panel Level redistribution processing, has the advantages of more Input/Output ports (I/O) and better integration flexibility, and is widely used in the semiconductor industry.

In Wafer Level or Panel Level Fan-out Packaging technology, wafer warpage or panel warpage often occurs due to differences in the thermal expansion coefficients of the redistribution layer, the chip and the molding layer. Warpage may also occur due to the multitude of materials that undergo multiple production steps at different temperatures, which leave residual stresses induced by mismatch of thermal strains and strains due to chemical processes. Meanwhile, stress is continuously accumulated in the process of curing and forming the epoxy resin molding compound (Epoxy Molding Compound, or EMC), which causes more warpage to occur, leading to increased difficulties in subsequent steps during the wafer or panel processing. Furthermore, warpage can also limit the maximum size of the wafer or panel used as support substrate in the packaging process and reduce the routing accuracy of the redistribution layer.

### SUMMARY

To solve the above technical problems, the present disclosure provides a composite carrier, method of making and method of using the composite carrier in semiconductor packaging.

In the first aspect, the present disclosure provides a composite carrier, which can be used as a support carrier in a Wafer Level or Panel Level Fan-out Package process. The composite carrier comprises: a first support layer, a second support layer, and a stress absorption layer. The stress absorption layer is sandwiched between the first support layer and the second support layer.

In some embodiments, the stress absorption layer has a Young's modulus of 1 MPa to 100 MPa. Alternatively, or additionally, the Poisson's ratio of the stress absorption layer is 0.30 to 0.499.

In some embodiments, the stress absorption layer comprises a polymer layer having viscoelasticity.

In some embodiments, the polymer layer having viscoelasticity comprises a silicone layer.

In some embodiments, the thickness of the stress absorption layer is 10 μm to 500 μm.

In some embodiments, the thickness of the first support layer and the thickness of the second support layer are each greater than the thickness of the stress absorption layer.

In some embodiments, the thickness of the first support layer is 400 μm to 3000 μm.

In some embodiments, the thickness of the second support layer is 400 μm to 3000 μm.

In the second aspect, the present disclosure also provides a method of preparing a composite carrier, which can be used as a support carrier in a semiconductor packaging process. The preparation method comprises providing a first support layer; forming a stress absorption layer on a surface on one side of the first support layer; and providing a second support layer and attaching the second support layer to a surface on one side of the stress absorption layer facing away from the first support layer.

In some embodiments, the preparation method further comprises: curing the stress absorption layer to achieve adhesion of the first and the second support layer with the stress absorption layer.

In the third aspect, the present disclosure further provides a semiconductor packaging method, including: providing a composite carrier, and forming a package on one surface of the composite carrier.

In some embodiments, forming a package on a surface on one side of the composite carrier includes: providing at least one semiconductor device, and attaching the active side of the semiconductor device to a surface on one side of the composite carrier; forming a molding layer; the molding layer covering the semiconductor device and exposed area of a surface on one side of the composite carrier, which faces the at least one semiconductor device; removing the composite carrier to expose the active side of the at least one semiconductor device; and forming a connection structure on active side of the at least one semiconductor device. The first connection structure is configured to connect to an external device.

In some embodiments, forming a package on a surface on one side of the composite carrier includes: providing at least one semiconductor device and attaching a passive side of the at least one semiconductor device to a surface on one side of the composite carrier; forming a molding layer; the molding layer covering the at least one semiconductor device and exposed portions of a surface on one side of the composite carrier, which faces the at least one semiconductor device; thinning the molding layer until the active surface of the at least one semiconductor device is exposed; forming a connection structure on the active surface of the at least one semiconductor device. The second connection structure is configured to connect to an external device; and removing the composite carrier.

In some embodiments, forming a package on a surface on one side of the composite carrier includes: forming a redistribution layer on a surface on one side of the composite carrier; providing at least one semiconductor device and attaching the active side of the at least one semiconductor device to a surface on one side of the redistribution layer facing away from the composite carrier; forming a molding layer; the molding layer covering the at least one semiconductor device and exposed portions of a surface of the redistribution layer facing the at least one semiconductor device; removing the composite carrier; and forming the third connection structure on a surface on one side of the redistribution layer facing away from the at least one semiconductor device. The third connection structure is configured to connect to an external device.

Compared with the current technology, the technical scheme according to certain embodiments has the following advantages. When the composite carrier is used in a semiconductor packaging process, the first support layer and the second support layer are used to provide a support force for the package, and the stress absorption layer is used to absorb stress generated in the packaging process, thus reducing or eliminating wafer or panel warpage, which is beneficial to reduce the difficulty of subsequent wafer or panel processing steps, and is also beneficial to reduce the impact of warpage on the size of the carrier and redistribution wiring accuracy.

### BRIEF DESCRIPTION OF THE DRAWINGS

FIG. 1 is a schematic diagram of a composite carrier according to an embodiment of the present disclosure.

FIG. 2 is a flow chart illustrating a method for preparing a composite carrier according to an embodiment of the present disclosure.

FIG. 3 is a schematic diagram illustrating cross sections of a composite carrier being formed using the method for forming a composite carrier shown in FIG. 2.

FIG. 4 is a flow chart illustrating a semiconductor packaging method according to an embodiment of the present disclosure.

FIG. 5 is a flow chart illustrating further steps of forming a package on a surface on one side of the composite carrier in the semiconductor packaging method illustrated in FIG. 4 according to certain embodiments.

FIG. 6 is a schematic diagram illustrating cross sections of a semiconductor package being formed on one side of the composite carrier using the method for forming a package shown in FIG. 5 according to certain embodiments.

FIG. 7 is a schematic diagram illustrating a composite carrier being removed according to an embodiment of the present disclosure.

FIG. 8 is a flow chart illustrating further steps in the semiconductor packaging method illustrated in FIG. 4, showing a package being formed on a surface on one side of the composite carrier according to certain embodiments.

FIG. 9 is a schematic diagram illustrating cross sections of a semiconductor package being formed on one side of the composite carrier using the method for forming a package shown in FIG. 8 according to certain embodiments.

FIG. 10 is a flow chart illustrating further steps of forming a package on a surface on one side of the composite carrier according to the semiconductor packaging method shown in FIG. 4.

FIG. 11 is a schematic diagram illustrating cross sections of a semiconductor package being formed on one side of the composite carrier using the method for forming a package shown in FIG. 10 according to certain embodiments.

### DETAILED DESCRIPTION OF THE EMBODIMENTS

In order that the above objects, features and advantages of the present disclosure can be more clearly understood, a further description of aspects of the present disclosure will be provided below. It should be noted that, without conflict, the embodiments of the present disclosure and features in the embodiments can be combined with each other.

In the following description, numerous specific details are set forth to provide a thorough understanding of the present disclosure, but the present disclosure may also be implemented in other ways different from those described herein. It is obvious that the embodiments in the specification are only some, but not all, embodiments of the disclosure.

In combination with the background technologies, due to the mismatch in thermal expansion coefficients of the materials in a semiconductor package, such as the bonding layer, the redistribution layer, the chip, the molding layer and the like, the packaging process will generate stress, causing the wafer or panel to have warpage. In addition, in Wafer Level or Panel Level Fan-out Packaging process, there is typically a support carrier to secure and support each package, the support carrier has some rigidity, which is also one of the main sources of warpage and stress. In the related technologies, to obtain better packaging efficiency, it is expected that more semiconductor devices can be assembled in a single package. Panel Level Fan-out Packages become a development direction, and Panel Level Packages require a support carrier to have a larger size. However, larger Panel Level Fan-out Packages and support carriers result in increased warpage, thus limiting the maximum size of the panels and support carriers. When the wafer or panel has warpage, it not only makes subsequent processing more difficult, but also affects redistribution wiring accuracy.

To solve the above technical problems, an embodiment of the present disclosure provides a composite carrier, a manufacturing method and a semiconductor packaging method, wherein the composite carrier is used as a support carrier in the Wafer Level or Panel Level Fan-out Packaging process, and the composite carrier includes: a first support layer, a second support layer and a stress absorption layer. The stress absorption layer is sandwiched between the first support layer and the second support layer. When the composite carrier is used in a semiconductor packaging process, the first support layer and the second support layer provides a support force for the package, and the stress absorption layer absorbs stress generated in the packaging process, thus reducing or eliminating wafer warpage or panel warpage. The reduced warpage is beneficial to lessening the difficulty in subsequent wafer or panel processing steps, and is also beneficial to reducing the impact of warpage on the size of the carrier and redistribution wiring accuracy.

The composite carrier, the preparation method and the semiconductor packaging method according to certain embodiments are described below with reference to the accompanying drawings.

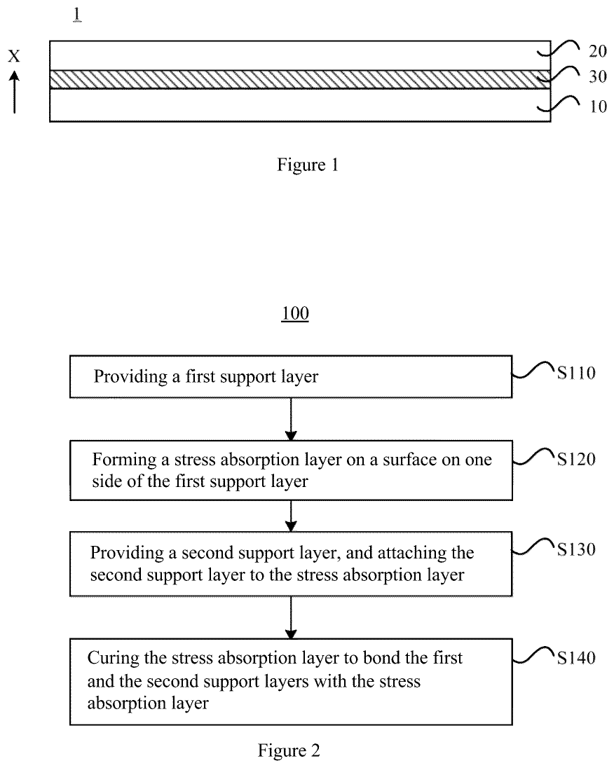

FIG. 1 is a schematic diagram of the structure of a composite carrier provided in an embodiment of the present disclosure. Referring to FIG. 1, the composite carrier 1 is used as a support carrier in the Wafer Level or Panel Level Fan-out Packaging process for providing support and fixation to each package body, and for absorbing stress generated in the packaging process. The composite carrier 1 includes: a first support layer 10, a second support layer 20, and a stress absorption layer 30. The stress absorption layer 30 is sandwiched between the first support layer 10 and the second support layer 20.

As shown in FIG. 1, according to certain embodiments, the composite carrier 1 is in a sandwich structure; along the stacked direction X, the composite carrier 1 includes a first support layer 10, a stress absorption layer 30, and a second support layer 20, which are sequentially stacked. In some embodiments, each of the first support layer 10 and the second support layer 20 is made of a rigid material, and the rigid materials can be glass and/or stainless steel. The first support layer 10 and the second support layer 20 each have a flat surface, and a package body can be subsequently formed on the flat surface according to a packaging method using the composite carrier to fix and support each package body. The stress absorption layer 30 is a layer including a flexible material, and the flexible material can be selected from materials with ultra-high elasticity, reversible elasticity, deformability, and low Young's modulus, such as silicone. The stress absorption layer 30 is configured to absorb stress generated in the packaging process to form the package body (such as the process for forming a bonding layer, a molding layer or a redistribution layer), and can increases the strain capacity and reduces the stresses in the package body and/or at the interface between the package body and the composite carrier, thus reducing the degree of wafer or panel warpage. The decreased warpage is beneficial to reducing the difficulty in subsequent wafer or processing steps, and is also beneficial to reducing the impact of warpage on the size of the carrier and redistribution wiring accuracy.

In some embodiments, each of the first and second support layers has a Young's Modulus of 10 GPa-150 GPa. In some embodiments, each of the first and second support layers has a Young's Modulus equal to or greater than about 50 GPa. For example, each of the first and second support layers may be or may include a layer of glass or stainless steel. In some embodiments, one of the first and second support layers may be or may include a layer of glass and the other a layer of stainless steel. It should be noted that, according to certain embodiments, the materials and thicknesses of the first support layer 10 and the second support layer 20 are not limited to what is disclosed herein and can be the same or different. Each of the first support layer 10, the second support layer 20, and the stress absorption layer 30 can have a single film structure or a composite film structure.

In some embodiments, the stress absorption layer 30 has a Young's modulus of 1 MPa to 100 MPa. Alternatively, or additionally, the Poisson's ratio of the stress absorption layer is 0.30 to 0.499.

In some embodiments, Young's modulus is used to characterize the ability of the stress absorption layer 30 to resist elastic deformation, the magnitude of which reflects the ease of elastic deformation of the stress absorption layer 30, and its value reflects the difficulty of the stress absorbing layer 30 to undergo elastic deformation. The smaller the value of the Young's modulus, the greater the elasticity of the stress absorbing layer 30, and a certain elastic deformation will occur under a smaller stress, thereby reducing or completely absorbing the stress, which is beneficial in reducing warpage.

In this embodiment, the stress absorption layer 30 undergoes elastic deformation under stress, and the elastic deformation includes longitudinal deformation and transverse deformation. Longitudinal deformation refers to the deformation of the stress absorption layer 30 along the stacking direction X, and the transverse deformation refers to the deformation of the stress absorption layer 30 along any directions parallel to the upper surface of the stress absorption layer 30 (perpendicular to the stacking direction X). The ratio of the transverse deformation to the longitudinal deformation is called Poisson's ratio, which is an elastic constant reflecting the transverse deformation of the stress absorption layer 30.

In some embodiments, to achieve better stress absorption, the stress absorption layer has a Young's modulus of 1 MPa to 50 Mpa and/or a Poisson's ratio of 0.40 to 0.499. In some embodiments, the stress absorption layer 30 comprises a polymer layer, such as a viscoelastic polymer layer having significant viscoelasticity.

In some embodiments, the polymer layer has ultrahigh elasticity and reversible stretchability. Under stress, the polymer layer undergoes elastic deformation along the stacking direction, and the polymer layer is compressed or stretched. The polymer layer also has high viscosity, enabling it to bond with the first support layer 10 located below it and the second support layer 20 located above it, forming a stable composite carrier structure.

In some embodiments, the viscoelastic polymer layer comprises a silicone layer.

In other embodiments, the material of the polymer layer can also be other elastic materials known to those skilled in the technologies, such as an elastomer, and is not limited to what is disclosed herein.

In some embodiments, as shown in FIG. 1, the thickness of the stress absorption layer 30 is about 10 μm to 500 μm.

In some embodiments, the thickness of the stress absorption layer 30 is about 100 μm.

In some embodiments, as shown in FIG. 1, the thickness of the first support layer 10 and the thickness of the second support layer 20 are each greater than the thickness of the stress absorption layer 30.

In some embodiments, as shown in FIG. 1, the thickness of the stress absorption layer 30 is about 200 μm, the thickness of the first support layer 10 is about 400 μm, the thickness of the second support layer 20 is about 500 μm, and each of the thickness of the first support layer 10 and the thickness of the second support layer 20 is greater than the thickness of the stress absorption layer 30.

In some embodiments, the thickness of the first support layer is about 400 μm to 3000 μm. The thickness of the second support layer is about 400 μm to 3000 μm.

In some embodiments, the thickness of the first support layer and the second support layer ranges from 400 μm to 3000 μm. The thickness of the first support layer and the thickness of the second support layer can be equal or different and are not limited what is disclosed herein. In some embodiments, by making one of the first and second support layers significantly thinner than the other, a balance of stress absorption and strength for support can be reached. For example, the thickness of the first support layer is greater than the thickness of the second support layer by at least 100 μm, or vice versa.

According to certain embodiments, a method 100 for manufacturing a composite carrier is provided. The composite carrier is used as a support carrier in a semiconductor packaging process. As shown in FIG. 2, the method for manufacturing a composite carrier 100 comprises: (S110) providing a first support layer, and (S120) forming a stress absorption layer on a surface on one side of the first support layer.

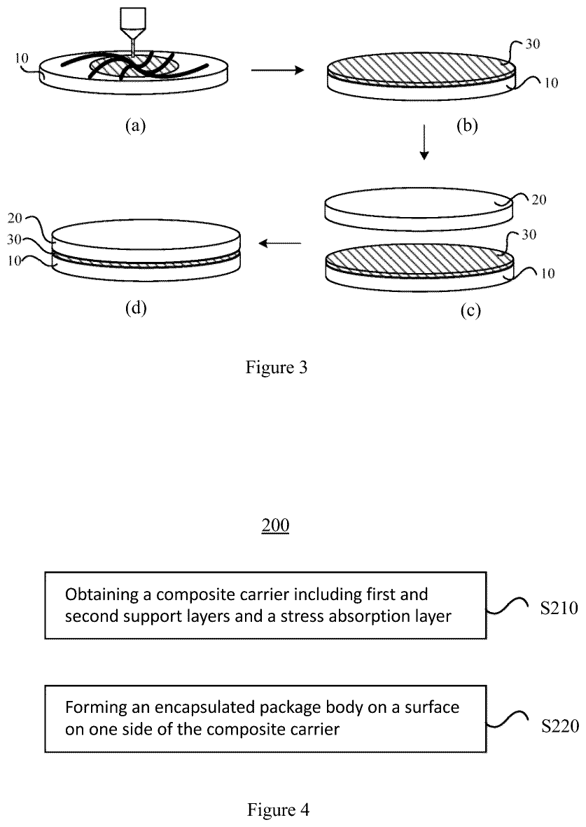

Referring to FIG. 3, a stress absorption layer is coated on the upper surface of the first support layer 10, using, for example, spin coating, spread coating, spray coating, or other coating methods known to those skilled in the technologies, which are not limited to what is described herein.

The method 100 further comprises (S130) providing a second support layer, and attaching the second support layer to a surface on one side of the stress absorption layer, which faces away from the first support layer.

Referring to FIG. 3, the second support layer 20 is disposed on a surface on one side of the stress absorption layer 30 facing away from the first support layer 10, that is, the stress absorption layer 30 is sandwiched between the first support layer 10 and the second support layer 20 and is attached to the first support layer 10 and the second support layer 20, so as to form a sandwich type composite carrier.

It should be noted that FIG. 3 only illustrates that the composite carrier is a circular flat plate but does not limit the preparation method of the composite carrier provided by the embodiment of the present disclosure. In other embodiments, the composite carrier can be configured in other shapes, such as a rectangular flat plate, and is not limited to the shapes described herein.

In some embodiments, as shown in FIG. 2, the method 100 further comprises (S140) curing the stress absorption layer to bond the first and the second support layer with the stress absorption layer.

In this step, the stress absorption layer 30 is cured using, for example, heating or baking, and after the stress absorption layer 30 absorbs heat, the hardness of the stress absorption layer 30 is increased, and the first support layer 10 and the second support layer 20 are bonded to the stress absorption layer 30.

In some embodiments, the stress absorption layer 30 is prepared from a material in a solution state or a molten state, and has a certain fluidity. In this case, after the stress absorption layer 30 is coated on a surface on one side of the first support layer 10, the stress absorption layer 30 is heated at a low temperature (e.g., 150° C., 120° C., or 100° C.) for a preset period of time (e.g., 30 minutes at 150° C., one hour at 120° C., or two hours at 100° C.) to reduce the fluidity and enhance the adhesiveness of the stress absorption layer. After the stress absorption layer is heated at the low temperature for the preset period of time, the stress absorption layer does not flow easily and is not completely cured. The adhesiveness of the stress absorption layer is also enhanced. Then the second support layer is placed above the stress absorption layer, and the method proceeds to heat the stress absorption layer to completely solidify the stress absorption layer 30, whereby the stress absorption layer 30, the first support layer 10 and the second support layer 20 form an adhesive structure, and thus the preparation of the composite carrier is completed.

On the basis of the above embodiments, the embodiments of the present disclosure also provide a semiconductor packaging method 200 using the above-described composite carrier.

As shown in FIG. 4, the semiconductor packaging method 200 includes (S210) providing any one of the composite carriers, and (S220) forming the package on a surface on one side of the composite carrier.

In the semiconductor packaging processes, the composite carrier is arranged below the package in the form of a substrate and is used for fixing and supporting components of the package during the packaging process. The composite carrier is typically a temporary carrier, which is removed at the end of the packaging process or during the packaging process when the packaging direction is changed.

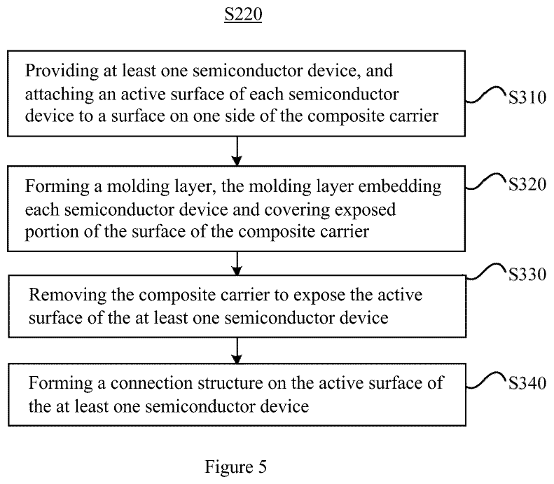

In some embodiments, as shown in FIGS. 5 & 6, (S220) “forming a package on a surface on one side of a composite carrier” includes (S310) providing at least one semiconductor device, and attaching an active surface of the at least one semiconductor device to a surface on one side of the composite carrier.

In some embodiments, the at least one semiconductor device 3 includes but is not limited to a die, a chip, and a wafer. Each of the at least one semiconductor device 3 includes a passive surface and an active surface disposed opposite to each other, the active surface is provided with bonding sites, and is electrically connected to the first connection structure 5 (or the redistribution layer) prepared in a subsequent step.

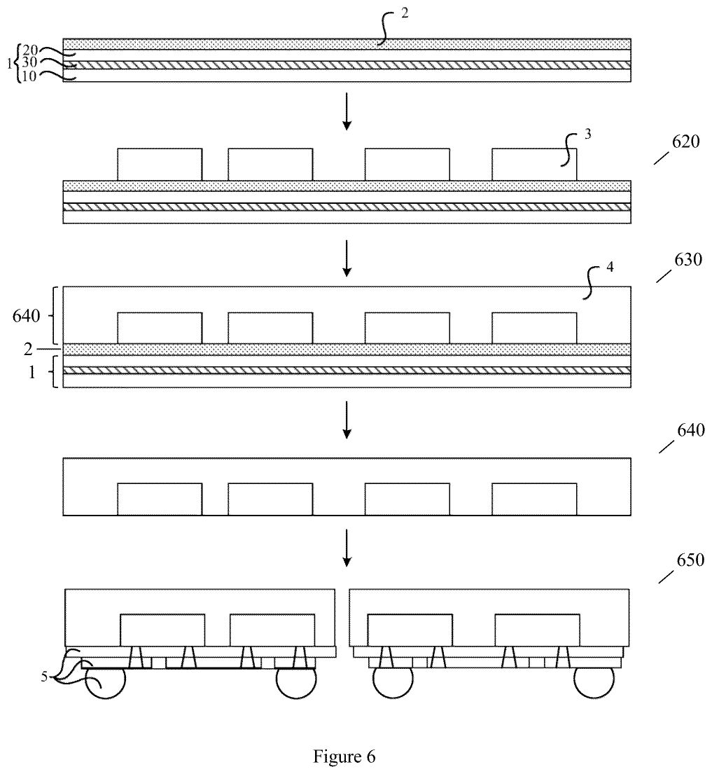

In this embodiment, combined with FIG. 6, the assembly method is face-down process flow, and the active surface of each of the at least one semiconductor device 3 faces the composite carrier 1, i.e., the active surface of each of the at least one semiconductor device 3 faces downward.

In some embodiments, as shown in FIGS. 5 & 6, (S310) “attaching an active surface of a semiconductor device to a surface on one side of a composite carrier” is carried out by forming a bonding layer 2 on a surface on one side of the composite carrier 1, and attaching the active face of each of the at least one semiconductor device 3 to the surface on one side of the bonding layer 2 facing away from the composite carrier 1, resulting in structure 620 shown in FIG. 6.

In some embodiments, the bonding layer 2 can be formed by taping and/or coating process, and then the bonding layer 2 is baked to improve adhesion of the bonding layer, and the active surface of the at least one semiconductor device 3 is attached to the bonding layer 2.

In some embodiments, as shown in FIGS. 5 & 6, (S220) “forming a package on a surface on one side of a composite carrier” further includes (S320) forming a molding layer. The molding layer embeds the at least one semiconductor device and covers exposed portions of the surface of the composite carrier facing the at least one semiconductor device, resulting in structure 630 shown in FIG. 6. Structure 630 includes a molded package body 640 formed on the composite substrate 1. The molded package body 640 includes the at least one semiconductor device encapsulated in the molding layer 4

In some embodiments, the molding layer 4 can be prepreg, which can cover all semiconductor devices, and also cover the surface of the bonding layer 2 which is not covered by the semiconductor device 3. The prepreg comprises one or more combinations of epoxy, polyethylene, polypropylene, polyolefin, polyamide, polyurethane, and the like. The molding layer 4 can be made of a liquid or powder epoxy resin, etc., and covers not only all the semiconductor devices 3 but also the surface of the bonding layer 2 not covered by the semiconductor devices 3. In some embodiments, forming the molding layer 4 includes at least one thermal process (e.g., a curing process) that causes thermal stress. With the use of the composite carrier 1, the thermal stress is absorbed by the stress absorption layer 30 and does not cause significant warpage of the structure 630.

In some embodiments, as shown in FIGS. 5 & 6, (S220) “forming a package on a surface on one side of a composite carrier” further includes (S330) removing the composite carrier to expose the active surface of the semiconductor device.

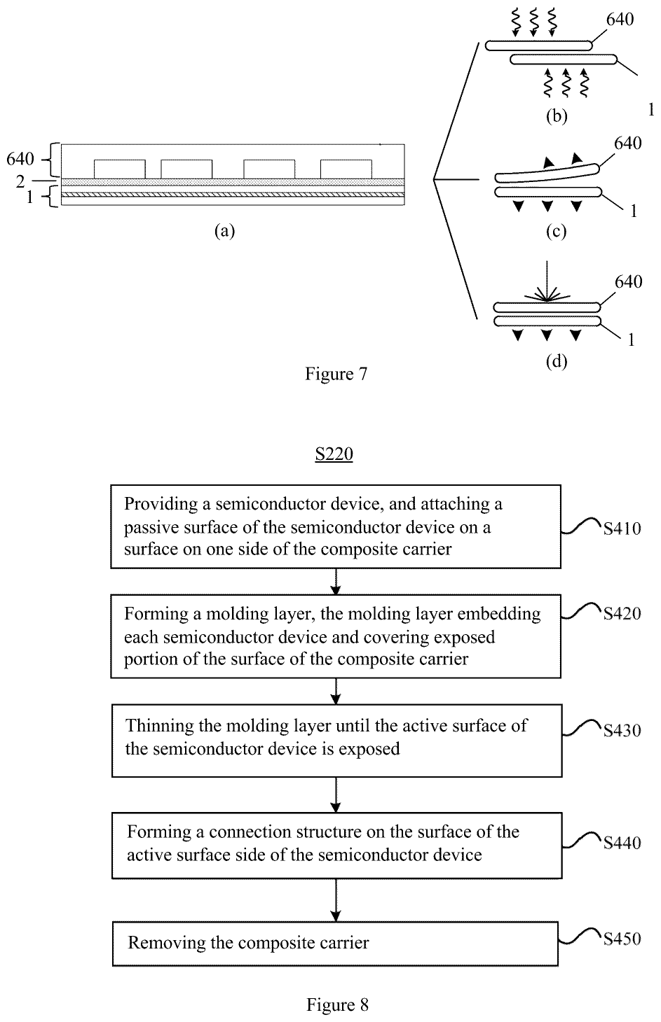

As shown in FIG. 7, the method for removing the composite carrier includes one of thermal debonding, mechanical debonding and laser debonding, and the method for removing the composite carrier is determined according to the support layer on one side of the package. For example, if the support layer on one side of the package is a glass layer and the stress absorption layer is transparent, any one of thermal debonding, mechanical debonding and laser debonding can be used to remove the composite carrier; if the support layer on the side forming the package is a stainless steel layer or if the support layer on the side forming the package is a glass layer and the stress absorption layer is opaque, thermal debonding and/or mechanical debonding is used to remove the composite carrier.

It should be noted that FIG. 6 only illustrates the formation of the package on one side of the second support layer 20 but does not constitute a limitation of the semiconductor packaging method provided by the embodiment of the present disclosure. In other embodiments, the package can be formed on a surface on one side of the first support layer 10, which is not limited herein.

In some embodiments, as shown in FIGS. 5 & 6, (S220) “forming a package on a surface on one side of a composite carrier” further includes (S340) forming the first connection structure on an active surface side of the semiconductor device.

In some embodiments, the first connection structure 5 is electrically connected to the active surface of the semiconductor device 3, and the first connection structure 5 is used to connect to the external devices, thus realizing the electrical interconnection between the semiconductor device 3 and the external devices. Illustratively, as shown in FIG. 6 (structure 650), the first connection structure 5 includes the redistribution layers and solder balls, the redistribution layer includes at least one patterned metal layer, the redistribution layer is electrically connected to the solder balls and the active surface of the semiconductor device 3, such that the semiconductor device 3 is electrically connected to the external devices through the redistribution layers and the solder balls.

The redistribution layer in some embodiments can be formed in the following process: a photo-thermal conversion layer (Light To Heat Conversion Release Coating (LTHC) Ink), a polymer layer (such as polyimide), a seed layer (including at least one of copper and titanium) and a photoresist layer are sequentially deposited on a surface of the molding layer 4 on one side where the active surface of the semiconductor device 3 is exposed; the photoresist layer is exposed and developed to form a redistribution layer pattern; the redistribution layer is formed by an electroplating process; the photoresist layer is then removed; and the residual seed layer is removed in an etching process. In the case that the redistribution layer includes a plurality of film layers, after the first redistribution layer is formed, a photoresist layer is formed over the first redistribution layer, the steps of exposure, development, electroplating, and the like are repeated to form the second redistribution layer, and so on, until all redistribution layers are formed.

In some embodiments, as shown in FIGS. 8 & 9, (S220) “forming a package on a surface on one side of a composite carrier” includes (S410) providing at least one semiconductor device, and attaching a passive surface of the semiconductor device on a surface on one side of the composite carrier.

In some embodiments, the semiconductor device 3 includes but is not limited to a die, a chip, and a wafer. The semiconductor device 3 includes a passive surface and an active surface disposed opposite to each other, and the active surface is provided with bonding sites and electrically connected to the second connection structure 6 (or the redistribution layer) prepared in a subsequent step.

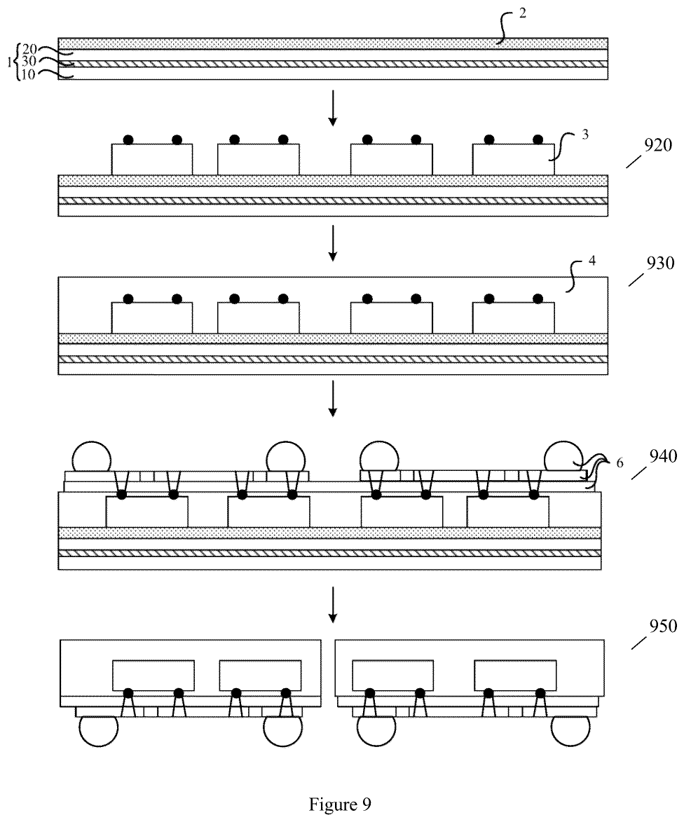

In this embodiment, combined with FIG. 9, the assembly method is face-up process flow, and the active surface of the semiconductor device 3 faces away from the composite carrier 1, i.e., the active surface of the semiconductor device 3 faces upward, resulting in structure 920 shown in FIG. 9.

As shown in FIGS. 8 & 9, (S220) “forming a package on a surface on one side of a composite carrier” further includes (S420) forming a molding layer. The molding layer covers the semiconductor device and covers a side surface of the composite carrier facing the semiconductor device, resulting in structure 930 shown in FIG. 9.

In some embodiments, the molding layer 4 covers all the semiconductor devices 3 and exposed portions of the surface of the bonding layer 2 not covered by the at least one semiconductor device. The preparation method of the molding layer 4 is similar to (S320) and is thus not repeated here.

As shown in FIGS. 8 & 9, (S220) “forming a package on a surface on one side of a composite carrier” further includes (S430) thinning the molding layer until the active surface of the semiconductor device is exposed.

In some embodiments, the molding layer 4 formed in step (S420 completely covers the semiconductor device 3, that is, the active surface of the semiconductor device 3 is also covered, in this step, Chemical Mechanical Polishing (Chemical Mechanical Polishing, CMP) and/or grinding processes can be used to thin the molding layer 4, until the active surface of the semiconductor device 3 covered by the molding layer 4 is exposed.

As shown in FIGS. 8 & 9, (S220) “forming a package on a surface on one side of a composite carrier” further includes (S440) forming the second connection structure on the surface of the active surface side of the semiconductor device, resulting in structure 940 shown in FIG. 9.

In some embodiments, the second connection structure 6 is electrically connected to the active surface of the semiconductor device 3, the second connection structure 6 is used to connect to an external device, thus realizing the electrical interconnection between the semiconductor device 3 and the external device. As shown in FIG. 9, the second connection structure 6 includes the redistribution layer and solder balls, the redistribution layer includes at least one patterned metal layer. In some embodiments, as discussed above, the redistribution layer includes multiple layers of different materials and the preparation method for forming the redistribution layer may include processing steps at different temperatures for forming the different layers of materials. These processes often cause thermal stress that may cause warpage but with the use of the composite carrier 1, the stress is absorbed by the stress absorption layer and does not result in significant warpage.

As shown in FIGS. 8 & 9, (S220) “forming a package on a surface on one side of a composite carrier” further includes (S450) removing the composite carrier to obtain the package(s) shown as structure 950 in FIG. 9.

In this step, one of thermal debonding, mechanical debonding and laser debonding can be used to remove the composite carrier.

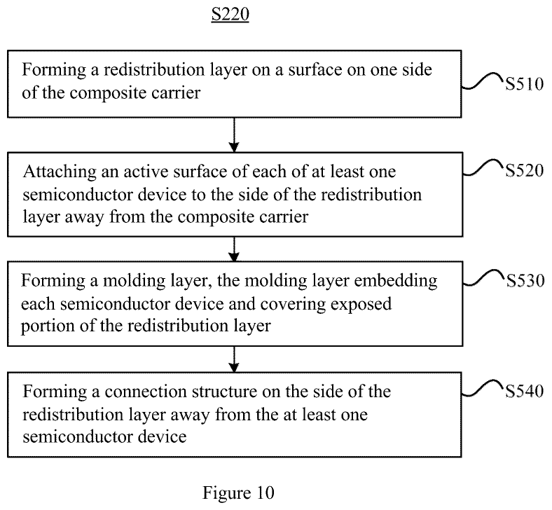

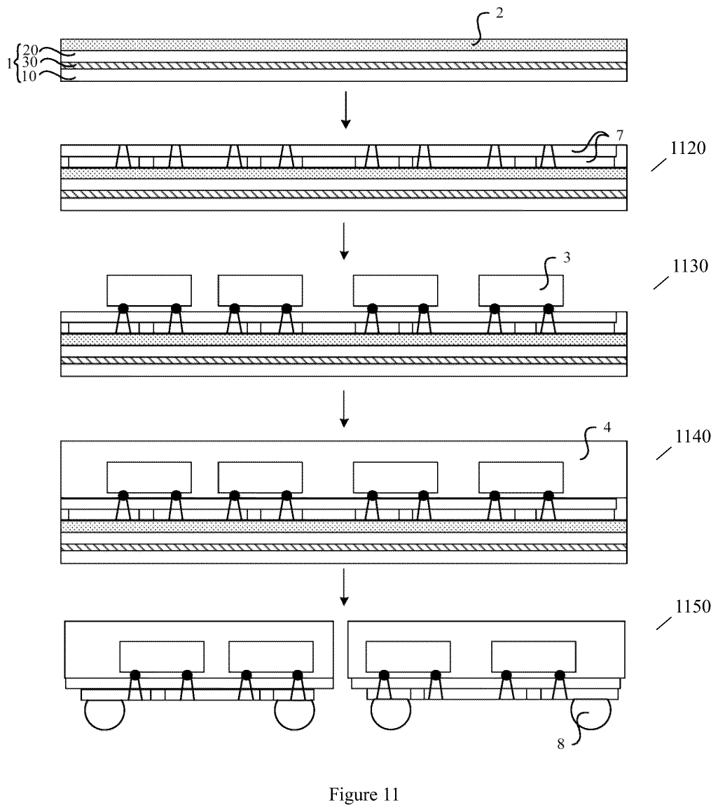

In some embodiments, as shown in FIG. 10, (S220) “forming a package on a surface on one side of the composite carrier” includes (S510) forming a redistribution layer on a surface on one side of the composite carrier, resulting in structure 1120 shown in FIG. 11.

In this embodiment, with reference to FIG. 11, the packaging method adopted is RDL-first process flow, i.e., the redistribution layer 7 is formed on a surface on one side of the composite carrier 1 first. In some embodiments, as discussed above, the redistribution layer includes multiple layers of different materials and the preparation method for forming the redistribution layer may include processing steps at different temperatures for forming the different layers of materials. These processes often cause thermal stress that may cause warpage, but with the use of the composite carrier 1, the stress is absorbed by the stress absorption layer and does not result in significant warpage in structure 1120, making it easier to attach the semiconductor devices to the redistribution layer and encapsulating the semiconductor devices in subsequent processes, which are discussed below.

As shown in FIG. 10, (S220) “forming a package on a surface on one side of the composite carrier” further includes (S520) providing the semiconductor device, and attaching an active surface of the semiconductor device to the surface of one side of the redistribution layer facing away from the composite carrier, resulting in structure 1130 shown in FIG. 11.

In some embodiments, the semiconductor device 3 includes but is not limited to a die, a chip, and a wafer. The semiconductor device comprises a passive surface and an active surface which are oppositely arranged, wherein the active surface is provided with bonding points, and the active surface of the semiconductor device 3 is electrically connected to the redistribution layer 7.

As shown in FIG. 10, (S220) “forming a package on a surface on one side of the composite carrier” further includes (S530) forming a molding layer 4, resulting in structure 1140 shown in FIG. 11. The molding layer covers the semiconductor device and covers the exposed portions of the redistribution layer not covered by the at least one semiconductor device.

The preparation method of the molding layer 4 is similar to (S320) and is not repeated here. Again, forming the molding layer 4 often induces thermal stress, which is absorbed by the stress absorption layer, and does not cause significant warpage in the structure 1140

When the molding layer 4 is made of a liquid or powder epoxy resin, the molding layer 4 not only covers all the semiconductor device 3 and the surface of the redistribution layer 7 not covered by the semiconductor device 3, but also fills the gap between the semiconductor device 3 and the redistribution layer 7.

As shown in FIG. 10, (S220) “forming a package on a surface on one side of the composite carrier” further includes (S540) removing the composite carrier, and forming third connection structure on the surface of one side of the redistribution layer facing away from the semiconductor device, resulting in structure 1150 shown in FIG. 11.

In some embodiments, use one of thermal debonding, mechanical debonding and laser debonding to remove composite carrier. The third connection structure 8 is configured to connect to an external device, and the third connection structure 8 is electrically connected to the redistribution layer 7, so that the electrical interconnection of the semiconductor device 3 and the external device is realized. Exemplarily, the third connection 8 is a solder ball.

In some embodiments, as shown in FIGS. 6, 9 and 11, the method for manufacturing a semiconductor device further includes dicing the molded package.

In some embodiments, each package includes at least one semiconductor device therein. The dicing process includes at least one of sawing, cutting, laser grooving, and plasma cutting.

It should be noted that in this document, relational terms such as “bottom” and “top” are only used to refer to an actual distinguish one entity or operation from another, without necessarily requiring or implying any such actual relationship or sequence between those entities or operations. Moreover, the terms “comprises,” “comprising,” or any other variation thereof, are intended to cover a non-exclusive inclusion, such that a process, method, material, or equipment that comprises a list of elements does not include only those elements but can include other elements not expressly listed or inherent to such process, method, material, or equipment. Without further limitation, an element defined by the statement “comprises a . . . ” does not exclude the presence of additional identical elements in a process, method, material, or equipment that includes the stated element.

The above descriptions are only specific embodiments of the present disclosure, enabling those skilled in the technology to understand or implement the present disclosure. Various modifications to these embodiments will be readily obvious that those skilled in the technology, and the generic principles defined herein can be applied to other embodiments without departing from the spirit or scope of the present disclosure. Thus, the present disclosure is not to be limited to the embodiments described herein but is to be accorded the widest scope consistent with the principles and novelty features disclosed herein.

1. A composite carrier configured to serve as a support carrier in Wafer Level or Panel Level Fan-out Packaging processes, the composite carrier comprising: a first support layer, a second support layer, and a stress absorption layer sandwiched between, and bonded to, the first support layer and the second support layer, wherein the stress absorption layer has a Young's modulus of 1 MPa to 100 Mpa and/or a Poisson's ratio of 0.30 to 0.499.

2. The composite carrier of claim 1, wherein the stress absorption layer has a Young's modulus of 1 MPa to 50 Mpa and/or a Poisson's ratio of 0.40 to 0.499.

3. The composite carrier of claim 1, wherein the stress absorption layer comprises a polymer layer having viscoelasticity.

4. The composite carrier of claim 3, wherein the polymer layer having viscoelasticity comprises a silicone layer.

5. The composite carrier of claim 1, wherein the thickness of the stress absorption layer is 10 μm to 500 μm.

6. The composite carrier of claim 5, wherein the thickness of the first support layer is greater than the thickness of the stress absorption layer, and the thickness of the second support layer is greater than the thickness of the stress absorption layer.

7. The composite carrier of claim 6, wherein the thickness of the first support layer is 400 μm to 3000 μm, and the thickness of the second support layer is 400 μm to 3000 μm.

8. The composite carrier of claim 7, wherein the stress absorption layer comprises a polymer layer having viscoelasticity.

9. The composite carrier of claim 8, wherein the polymer layer having viscoelasticity comprises a silicone layer.

10. A method of forming a semiconductor package in a set of Wafer Level or Panel Level Fan-out Packaging processes, comprising:
providing a composite carrier, the composite carrier including a first support layer, a second support layer, and a stress absorption layer sandwiched between, and bonded to, the first support layer and the second support layer, wherein the stress absorption layer has a Young's modulus of 1 MPa to 100 Mpa and/or a Poisson's ratio of 0.30 to 0.499; and
forming a package on a surface on one side of the composite carrier, the package including at least one semiconductor device, wherein forming the package on the surface on the one side of the composite carrier includes attaching the at least one semiconductor device to the composite carrier and forming a molded layer encapsulating the at least one semiconductor device, wherein forming the molded layer includes at least one thermal process causing first thermal stress that is absorbed by the stress absorption layer.

11. The method of claim 10, wherein forming the package on the surface on one side of the composite carrier further includes, before attaching the at least one semiconductor device to the composite carrier, forming a redistribution layer on the surface on the one side of the composite carrier, wherein attaching the at least one semiconductor device to the composite carrier includes attaching the at least one semiconductor device to the redistribution layer, wherein the redistribution layer includes multiple layers of different materials that are formed in processing steps at different temperatures, causing second thermal stress that is absorbed by the stress absorption layer.

12. The method of claim 10, wherein each of the at least one semiconductor device has a passive side that is attached to the surface on the one side of the composite carrier, wherein forming the package on the surface on one side of the composite carrier further includes forming a redistribution layer over the at least one semiconductor device, wherein the redistribution layer is coupled to an active side of each of the at least one semiconductor device, wherein the redistribution layer includes multiple layers of different materials that are formed in processing steps at different temperatures, causing third thermal stress that is absorbed by the stress absorption layer.

13. The method of claim 10, further comprising separating the composite carrier from the package.

14. The method of claim 10, wherein the stress absorption layer has a Young's modulus of 1 MPa to 50 Mpa and/or a Poisson's ratio of 0.40 to 0.499.

15. The method of claim 10, wherein the stress absorption layer comprises a polymer layer having viscoelasticity.

16. The method of claim 15, wherein the polymer layer having viscoelasticity comprises a silicone layer.

17. The method of claim 10, wherein the thickness of the stress absorption layer is 10 μm to 500 μm, wherein the thickness of each of the first support layer and the second support layer is greater than the thickness of the stress absorption layer and is in the range of 400 μm to 3000 μm.

18. A method of making a composite carrier for use as a support carrier in Wafer Level or Panel Level Fan-out Packaging processes, comprising:
providing a first support layer;
forming a layer of at least one stress absorption material on a surface of the first support layer;
attaching a second support layer to a side of the layer of the at least one stress absorption material facing away from the first support layer;
and curing the layer of the at least one stress absorption material to form a stress absorption layer sandwiched between, and bonded to, the first support layer and the second support layer, wherein the stress absorption layer has a Young's modulus of 1 MPa to 100 Mpa and/or a Poisson's ratio of 0.30 to 0.499.

19. The method of claim 18, wherein the stress absorption layer comprises a polymer layer having viscoelasticity.

20. The method of claim 19, wherein the thickness of the stress absorption layer is 10 μm to 500 μm, wherein the thickness of each of the first support layer and the second support layer is greater than the thickness of the stress absorption layer and is in the range of 400 μm to 3000 μm.
